(19) United States
(12) Patent Application Publication
(10) Pub. No.: US 2012/0308714 A1
(43) Pub. Date: Dec. 6, 2012

(54) REDUCED PRESSURE DEPOSITION APPARATUS AND REDUCED PRESSURE DEPOSITION METHOD

(75) Inventors: Tadahiro OHMI, Miyagi (JP); Akinobu TERAMOTO, Miyagi (JP)

(73) Assignee: CANON KABUSHIKI KAISHA, Tokyo (JP)

(21) Appl. No.: 13/490,753

(22) Filed: Jun. 7, 2012

Related U.S. Application Data
(62) Division of application No. 11/992,225, filed on Mar. 19, 2008, now abandoned.

(51) Int. Cl. C23C 16/44; H05B 33/10

(52) U.S. Cl. 427/66; 427/248.1

(57) ABSTRACT

In a deposited thin film for use in a semiconductor device or the like, adsorption of contaminants is a problem. In the case in which a gas pressure in a chamber is maintained in a viscous flow region, the adsorption of the organic substances is significantly decreased as compared with the case in which the gas pressure is maintained in a molecular flow region. The gas pressure is controlled so that it can be set in the molecular flow region when forming the deposited thin film, and set in the viscous flow region when such deposition is not being performed. Thus, the deposited thin film is formed with less contamination from the organic substances.

### CROSS-REFERENCE TO RELATED APPLICATIONS

This application is a divisional application of U.S. application Ser. No. 11/992,225, filed Mar. 19, 2008, which claims the benefit of priority of a national stage entry under 35 U.S.C. §371 of International Application No. PCT/JP2005/017339, filed Sep. 21, 2005. The contents of both of the applications mentioned above are hereby incorporated by reference herein in their entireties.

### BACKGROUND OF THE INVENTION

1. Technical Field

The present invention relates to a reduced pressure deposition apparatus and a reduced pressure deposition method, in which a film is formed under a lower pressure than atmospheric pressure without organic contamination.

2. Background Art

In general, as deposition apparatuses, there are an atmospheric deposition apparatus and a reduced pressure deposition apparatus. Of those, the atmospheric deposition apparatus is an apparatus in which deposition is performed in a chamber in a state being maintained at the atmospheric pressure. On the other hand, a deposition apparatus is an apparatus in which a deposited film is formed on a substrate by evaporating a raw material filled in an evaporating dish in a state where a pressure in the chamber is set to an extremely lower pressure than the atmospheric pressure. The atmospheric deposition apparatus is capable of forming the deposited film at a high growth rate because the deposition thereof is performed at the atmospheric pressure where a lot of gas molecules exist. However, there is a disadvantage that the atmospheric deposition apparatus is inferior in terms of uniformity of the deposited film.

On the other hand, in the reduced pressure deposition apparatus, as a result that mutual collisions of the gas molecules are reduced since the pressure in the chamber is low, there is an advantage that a concentration of the gas becomes uniform over a wide range, leading to uniformity of a thickness of the deposited film. In recent years, electronic devices such as a semiconductor device and a flat panel display device, which is manufactured by including a step of forming the film by using the deposition apparatus, have higher integration and more ultrafine structures. Along with this, the reduced pressure deposition apparatus capable of forming the uniform film has attracted attention.

It is pointed out that, also in the reduced pressure deposition apparatus as described above, slight contamination on the deposited film and a device becomes a problem when ultra preciseness of the device has come to be required. For example, in Japanese Unexamined Patent Application Publication (JP-A) No. H09-186057 (Patent Document 1), it is pointed out that there is a serious influence on the device by molecular contaminant, and accordingly, there is proposed a method of facilitating investigation into cause of a semiconductor device failure owing to the molecular contaminant and analysis of a failure occurrence mechanism owing thereto. As a method for this, in Patent Document 1, a deposition apparatus is proposed, which controllably adheres and grows a foreign object on a wafer in order to make it possible to set a level of controlling the contamination and a limit value of the influence of the contaminant on a process. Specifically, the proposed deposition apparatus positively deposits a variety of impurities, which can occur in the manufacturing process, on the wafer for each substance and for each concentration, thus making it possible to analyze the influence from the contaminant.

Meanwhile, in Japanese Unexamined Patent Application Publication No. H08-321448 (Patent Document 2), it is pointed out that, in the case of using a turbo-molecular pump for an exhaust system, the impurities are mixed into the deposited thin film, causing an adverse effect on characteristics of the semiconductor device. Accordingly, Patent Document 2 proposes a vacuum exhaust system capable of diagnosing that a cause of the adverse effect is that the gas molecules exhausted once and gas of the impurities and the like present on an exhaust side of the turbo-molecular pump are reversely diffused in the chamber, and capable of preventing such reverse diffusion.
Patent Document 1: JP H09-186057 A
Patent Document 2: JP H08-321448 A

### DISCLOSURE OF THE INVENTION

### Problem to be Solved by the Invention

Patent Document 1 only discloses that the influence from the contaminant is analyzed by depositing the impurities on the wafer for each substance and for each concentration, and does not point out a method or apparatus for reducing the contamination by the impurities.

Further, Patent Document 2 points out that, in order to prevent a backflow of the gas of the impurities, which is exhausted from the exhaust system, an auxiliary pump is connected to the exhaust side of the turbo-molecular pump, and the gas is introduced between the turbo-molecular pump and the auxiliary pump, whereby an inside of the chamber is evacuated, thus making it possible to prevent the reverse diffusion of the impurities from the exhaust side of the turbo-molecular pump to an intake side thereof. However, Patent Document 2 only proposes to prevent the backflow of the impurities from the exhaust system, and does not point out at all about the reduction and prevention of the contamination by the impurities which occur during the deposition step, and particularly, by organic substances.

It is an object of the present invention to provide a deposition apparatus capable of reducing the influence of the contamination on the deposited film based on findings about a relationship between the contamination and the pressure in the chamber in the deposition step.

It is another object of the present invention to provide a deposition apparatus capable of reducing the adhesion of the impurities, and particularly, of the organic substances.

It is still another object of the present invention to provide a deposition method in which the contamination by the organic substances can be reduced.

It is a more specific object of the present invention to provide a vacuum deposition apparatus, specifically, a reduced pressure deposition apparatus, that is free from such organic contamination, and does not cause dissociation/decomposition of the molecules.

### Means to Solve the Problem

According to an aspect of the present invention, there is provided a reduced pressure deposition apparatus, including: a deposition dish in a chamber, wherein a pressure of an atmosphere where a deposited film is formed is set to a gas pressure of a molecular flow region at a time of forming the deposited film, and the pressure of the atmosphere is set to a gas pressure of a viscous flow region at least in a certain period during a time when the deposited film is not formed.

In this case, it is desirable that the gas pressure of the molecular flow region at the time of forming the deposited film be approximately 1 mTorr or lower, and the gas pressure of the viscous flow region at the time when the deposited film is not formed be approximately 1 Torr or higher.

In accordance with a more specific aspect of the present invention, there is provided a reduced pressure deposition apparatus, in which a heating mechanism and a deposition dish are provided in a chamber to which a gas exhausting primary pump and a roughing pump are connected and to which a gas supply pipe that supplies high-purity inert gas such as argon, nitrogen krypton, and xenon is connected, wherein the atmosphere where the deposited thin film is formed is set to the gas pressure of the molecular flow region at the time of forming the deposited thin film, and the pressure of the atmosphere is set to the gas pressure of the viscous flow region in the certain period during the time when the deposited thin film is not being formed.

In accordance with a far more specific aspect of the present invention, there is provided a reduced pressure deposition apparatus, in which a gas exhausting primary pump is connected to a chamber including a stage onto which a substrate is placed, and including a deposition dish having a heating mechanism, onto which a deposition object is placed, and a roughing pump is connected in series to the primary pump directly or through intermediation of another pump such as a screw booster pump, inert purge gas is passed through an outlet-side purge port of the primary pump, and an outlet side of the primary pump, for example, a connecting portion thereof to the roughing pump, is set to a pressure that becomes a viscous flow region, wherein an inert gas supply pipe is connected to the chamber. It is preferable that the connecting portion between the inert gas supply pipe and the chamber includes an orifice, and it is preferable that a valve be provided upstream of the orifice, and that a pressure regulator and a pressure gauge be installed upstream of the valve.

Further, the present invention provides a reduced pressure deposition apparatus, including: a chamber that houses therein a substrate on which a deposited film is to be formed; and gas pressure regulating means for maintaining a pressure in the chamber in a molecular flow region, and changing the pressure from the molecular flow region to a viscous flow region, wherein contamination on the deposited film is thereby reduced. The gas pressure regulating means includes a pipe for introducing gas into the chamber, gas flow rate controlling means for regulating a flow rate of the gas supplied from the pipe to the chamber, and pump means for exhausting the gas in the chamber, and the gas flow rate controlling means and the pump means are controlled, thereby realizing gas pressures of the molecular flow region and the viscous flow region. It is preferable that the chamber includes a deposition dish onto which a raw material to be deposited is mounted; a support body that holds the substrate; and means for heating the deposition dish.

By the present invention as described above, it is possible to obtain a reduced pressure deposition apparatus suitable for depositing an organic EL material that is sensitive to the contamination.

According to another aspect of the present invention, there is provided a reduced pressure deposition method of performing deposition processing in a chamber capable of varying an inner pressure thereof, the reduced pressure deposition method including: a first step of maintaining a pressure in the chamber in a molecular flow region; and a second step of changing the pressure in the chamber from the molecular flow region to a viscous flow region, wherein contamination on the deposited film is thereby reduced. It is preferable that the deposition be performed during the first step, and the second step be performed during a period while the deposition is not being performed. It is preferable that a gas pressure in the chamber differ between the first step and the second step, and the gas pressure in the second step be higher than the gas pressure in the first step, that, in the first step, a gas pressure in the chamber be set to 0.1 mTorr to 1 mTorr so that the gas pressure is maintained in the molecular flow region, and in the second step, the gas pressure in the chamber is set to 1 Torr or higher so that the gas pressure is set in the viscous flow region, and that the gas pressure in the second step is 10 Torr or higher. The chamber is enabled to be supplied with inert gas and the chamber is enabled to be exhausted in advance, and a gas flow rate of the supplied inert gas is controlled and an exhaust velocity of the exhaustion is controlled, thereby realizing gas pressures of the molecular flow region and the viscous flow region.

According to the present invention, there is provided a reduced pressure deposition method, including: setting a pressure of an atmosphere where a deposited film is formed to a gas pressure of a molecular flow region at a time of forming the deposited film; and setting the pressure of the atmosphere to a gas pressure of a viscous flow region at least in a certain period during a time when the deposited film is not formed. It is preferable that the gas pressure of the molecular flow region at the time of forming the deposited film be approximately 1 mTorr or lower, and the gas pressure of the viscous flow region while the deposited film is not being formed be approximately 1 Torr or higher, and that a main component of the atmosphere at the time of forming the deposited film and at the time when the deposited film is not formed be inert gas of at least one of high-purity nitrogen, argon, xenon, and krypton.

The present invention also provides a deposition method for an organic EL film, including depositing the organic EL film by using the above-mentioned reduced pressure deposition method, a deposition method for an organic EL film, including the step of depositing the organic EL film by using the above-mentioned the reduced pressure deposition method, and a manufacturing method for an electronic device, including the step of: forming a film by using the above-mentioned reduced pressure deposition method.

### Effect of the Invention

According to the present invention, it was found out that the adsorption amount of the impurities, and particularly, of the organic substances to the substrate changes between the pressures in the chamber, in which the deposition is performed, of the molecular flow region and the viscous flow region. The adsorption amount of the organic substances is reduced by setting a period while the adsorption amount is low. Specifically speaking, in the present invention, the deposition is performed at the gas pressure of the molecular flow region, and the period while the gas pressure is in the viscous flow region, while the adsorption of the organic substances is a little, is set, thus making it possible to reduce the contamination by the organic adsorbate and the like.

The present invention can be applied not only to a case of forming a single layer but also to a case of depositing a multilayer film of Al or the like.

### BRIEF DESCRIPTIONS OF THE DRAWINGS

FIG. 1 is a graph showing a relationship between organic contamination and a gas pressure, which forms a base of the present invention.

FIG. 2 is a graph showing a relationship between the organic contamination and the gas pressure in a case where deposition is actually performed in accordance with experiment results shown in FIG. 1.

FIG. 3 is a block diagram showing a vacuum system including a reduced pressure deposition apparatus according to an embodiment of the present invention.

### DESCRIPTION OF SYMBOLS

21 processing chamber (deposition chamber)
31 substrate introduction chamber
22, 32 primary pump
23, 33 secondary pump
25 substrate
26 substrate holder
28, 38 pump valve
29 processing chamber gas introduction mechanism
41 deposition source chamber
42 deposition source container (deposition dish)
43 heater
44 shutter mechanism
291, 292 orifice
293 to 295 valve
296 pressure gauge

### BEST MODE FOR EMBODYING THE INVENTION

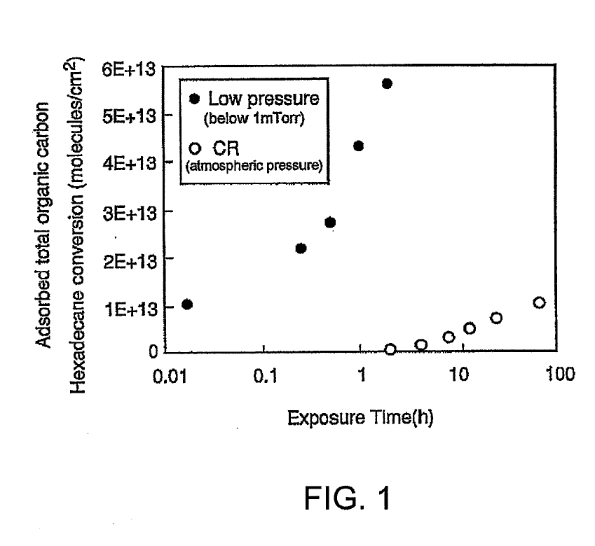

A description will be made of an experiment serving as a base of the present invention and results thereof with reference to FIG. 1. First, a semiconductor or glass substrate to be subjected to pressure-reduction treatment was delivered into a deposition chamber that performs reduced pressure deposition, and a pressure in the deposition chamber concerned was changed, whereby a relationship between the pressure in the deposition chamber and an amount of organic substances adsorbed to the substrate was investigated. Note that a vacuum system of a cluster type, which has a load lock chamber for delivering a substrate such as a semiconductor substrate into and out of the vacuum system, and includes, as a process chamber, the deposition chamber performing reduced pressure deposition, was used for the experiment. Here, the deposition chamber is a main constituent component of the reduced pressure deposition apparatus.

An axis of abscissas of FIG. 1 represents an exposure time, and an axis of ordinates thereof represents the adsorption amount of organic substances to the substrate. Here, the adsorption amount of the organic substances, which is represented on the axis of ordinates, is expressed as a form of amounts in which all the organic substances were converted into hexadecane with a molecular weight of 226.45. Black points in FIG. 1 denote results obtained by measuring the adsorption amounts of the organic substances adsorbed to the substrate in the process chamber maintained at a low pressure equal to or lower than 1 mTorr, and white points denote results obtained by measuring the adsorption amounts of the organic substances adsorbed to the substrate in the process chamber maintained at the atmospheric pressure.

As apparent also from FIG. 1, in the chamber maintained at the low pressure equal to or lower than 1 mTorr, the adsorption amount of the organic substances adsorbed to the substrate is large, and in addition, is radically increased with time. On the other hand, it is understood that, in the chamber maintained at the atmospheric pressure, the adsorption of the organic substances is hardly observed even after the substrate has been exposed for an hour. This stands for that, the lower the pressure in the chamber is, the larger the adsorption amount of the organic substances to the substrate is, and it is predicted that the adsorption amount of the organic substances is reduced as the pressure in the chamber rises.

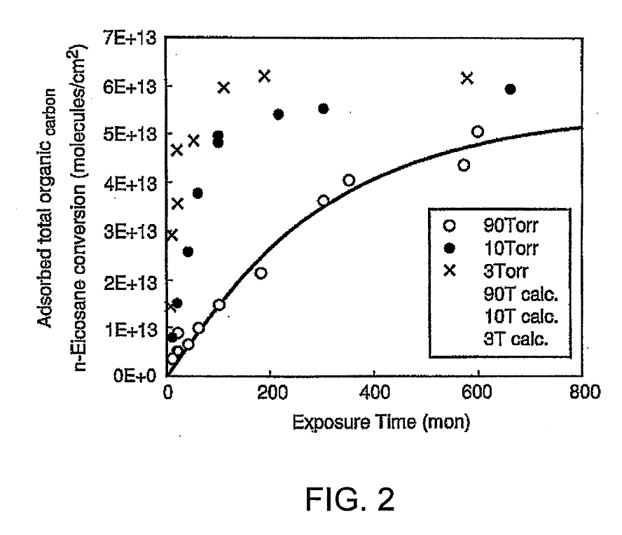

FIG. 2 shows results of an experiment that is based on the above-mentioned prediction. Here, amounts of organic carbons adsorbed to the substrate, which were converted into n-eicosane while the pressure in the chamber is set to 90 Torr, 10 Torr, and 3 Torr, are shown as the adsorption amounts of the organic substances. As apparent also from FIG. 2, the adsorption amount of the organic substance is the smallest in the case where the pressure is 90 Torr, and the adsorption amount of the organic substances is increased in order from the pressure of 10 Torr to the pressure of 3 Torr. Hence, it has been proven that the adsorption amount of the organic substances can be reduced by increasing the pressure even in a pressure-reduced state in which the pressure is lower than the atmospheric pressure.

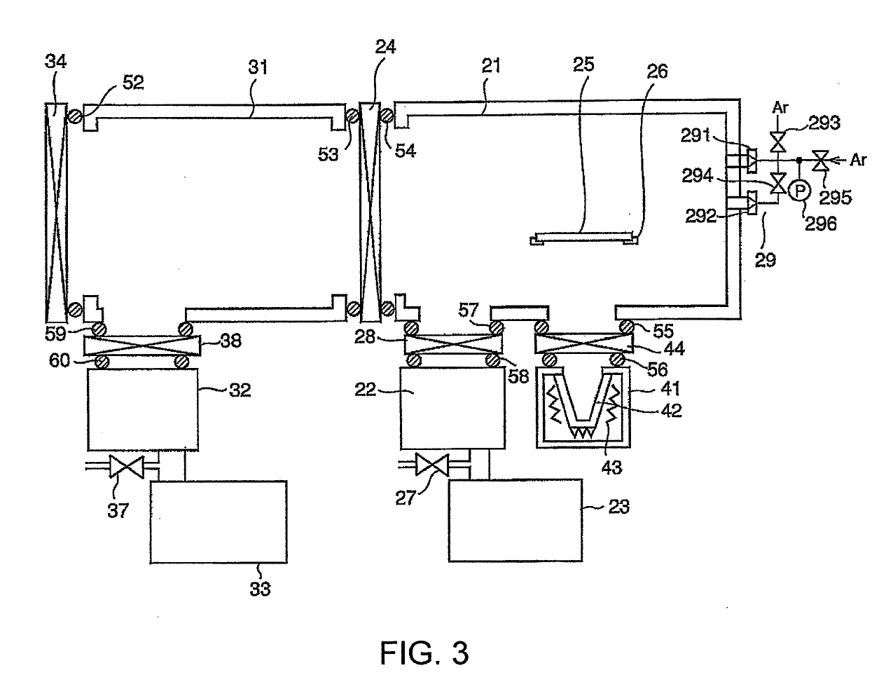

A description will be made of a deposition apparatus according to an embodiment of the present invention with reference to FIG. 3. The illustrated deposition apparatus includes: a processing chamber (deposition chamber) 21 that performs deposition processing; and a substrate introduction chamber (load lock chamber) 31 that is connected to the processing chamber 21 concerned while interposing a gate valve 24 therebetween, and delivers a substrate 25 such as a semiconductor substrate and a glass substrate into and out of the processing chamber 21.

Further, a substrate introduction door 34 is provided in the substrate introduction chamber 31, and the substrate is introduced into the substrate introduction chamber 31 through the substrate introduction door 34 concerned, and meanwhile, is delivered out of the substrate introduction chamber 31 therethrough. Further, a primary pump 32 and a secondary pump 33 are connected to the substrate introduction chamber 31 while interposing a pump gate valve 38 therebetween, and a pump purge gas introduction mechanism 37 is connected between the primary pump 32 and the secondary pump 33. This pump purge gas introduction mechanism 37 serves to suppress reverse diffusion of impurities from the secondary pump 33.

On the other hand, a primary pump 22 and a secondary pump 23 are connected to the processing chamber 21 while interposing a pump gate valve 28 therebetween, and a pump purge gas introduction mechanism 27 is connected between the primary pump 22 and the secondary pump 23. This pump purge gas introduction mechanism 27 also performs an operation of suppressing the reverse diffusion of impurities from the secondary pump 23. Further, a deposition source chamber 41 is provided below the processing chamber 21 while interposing a shutter mechanism 44 therebetween. In the deposition source chamber 41 concerned, there are provided: a deposition source container (deposition dish) 42 filled with a deposition raw material (for example, an organic EL material in the case of manufacturing an organic EL display device, and a material such as Al to be formed into a film by deposition in the case of manufacturing a semiconductor device); and a heater 43. The deposition raw material in the deposition source container 42 is heated by the heater 43 concerned. The shutter mechanism 44 opens at the time of deposition, and on the other hand, closes to shut the deposition during a period while the deposition is unnecessary. While the shutter mechanism 44 is open, the deposition raw material in the deposition source container 42 is heated and evaporated by the heater 43, and is deposited on the substrate 25 attached onto a substrate holder 26 in the processing chamber 21.

Further, in the illustrated processing chamber 21, a processing chamber gas introduction mechanism 29, which introduces gas into the processing chamber 21, is provided as a gas flow rate regulator, and as will be described later, gas necessary to maintain an inside of the processing chamber 21 in a molecular flow region or a viscous flow region is introduced into the processing chamber 21 through the processing chamber gas introduction mechanism 29. Note that, in the illustrated example, gaskets 52, 53, 54, 55, 56, 57, 58, 59 and 60 which are present in connecting portions of the respective spots and ensure airtightness thereof from the outside are provided. In terms of suppressing the organic substances which occur from these gaskets, it is preferable that, among these gaskets, the gaskets 52 and 56, which are present between the substrate introduction door 34 and the substrate introduction chamber 31 and between the deposition source chamber 41 and the shutter mechanism 44, respectively, be made of perfluoroelastomer, and the other gaskets 53, 54, 55, 57, 58, 59 and 60 be made of Cu.

A description will be made below mainly of operations of the processing chamber (deposition chamber) 21 according to the present invention, that is, of the reduced pressure deposition apparatus according thereto. In this embodiment, an atmosphere where the deposited thin film is formed is set to a gas pressure of the molecular flow region at the time of forming a deposited thin film, and the pressure of the atmosphere is set to a gas pressure of the viscous flow region during a certain period while the deposited thin film is not being formed. Specifically speaking, in the molecular flow region, the gas pressure in the processing chamber 21 is regulated in a range from 0.1 mTorr to 1 mTorr, and in the viscous flow region, the gas pressure is regulated at 1 Torr or higher, and preferably, at 10 Torr or higher.

In order to realize, in the processing chamber 21, the gas pressures which become the molecular flow region and the viscous flow region, a flow rate of gas, to be introduced, particularly, inert gas such as argon or nitrogen in this example, is controlled by the processing chamber gas introduction mechanism (gas flow rate regulator) 29, and exhaust amounts of the primary pump 22 and the secondary pump 23 and a flow rate of gas passed through the pump purge gas introduction mechanism 27 are regulated. Note that turbo-molecular pumps can be used as the primary pumps 22 and 32, and that auxiliary pumps can be used as the secondary pumps 23 and 33.

Here, in the case of forming the film in the molecular flow region while suppressing the gas pressure in the processing chamber 21 at the time of forming the deposited thin film at approximately from 0.1×10⁻³ to 1×10⁻⁵ Torr, the following expression is established among the flow rate f of the gas introduced into the processing chamber 21, the gas pressure P in the processing chamber 21, and an exhaust velocity S.

f=79P(Torr)·S(I/sec)

Here, when an exhaust velocity of the primary pump 22 is set to 1000 I/sec, and the gas pressure in the processing chamber 21 is set from 0.1 to 1 mTorr, the flow rate of the gas introduced into the processing chamber 21 can be expressed by the following expression.

$$\begin{matrix}f = 79 ( 1 \times {10}^{- 4} or 1 \times {10}^{- 3} ) {10}^{3} ( 1 \text{/} sec ) \\ = 7.9 cc \text{/} min ( 0.1 mTorr ) or 79 cc \text{/} min ( 1 mTorr )\end{matrix}$$

Specifically, in order to set the gas pressure in the processing chamber 21 in the molecular flow region, the flow rate f for the processing chamber 21 just needs to be maintained between 7.9 cc/mm and 79 cc/mm.

Meanwhile, in the case of changing the gas pressure in the processing chamber 21 during the period while the deposited thin film is not being formed to the pressure of the viscous flow region from 1 Torr to 10 Torr, for example, when the gas flow rate f for the processing chamber 21 is set to, for example, 103 cc/min, the exhaust velocity S just needs to be set to 12.6 (I/sec) at 1 Torr, and just needs to be set to 1.26 (I/sec) at 10 Torr.

It is possible to narrow down a range of the exhaust velocity S to the above-mentioned extent by throttling the pump valve 28 between the processing chamber 21 and the primary pump 22 or by increasing the flow rate of the gas passed through the primary pump 22 and the pump purge gas introduction mechanism 27.

Meanwhile, the illustrated processing chamber gas introduction mechanism 29 is composed of first and second orifices 291 and 292, first to third valves 293 to 295, and a pressure gauge 296. The first to third valves 293 to 295 are connected to generation sources that generate inert gas, that is, Ar in this case, and in this configuration, can constantly maintain the pressure in the processing chamber 21. For example, the first orifice 291 passes the gas at 1.5 cc/min, and when the second valve 294 is opened at this time, the second orifice 292 passes the gas at 1000 cc/min, whereby the pressure can be constantly maintained.

Further, a pressure regulator is provided upstream of the first valve 293 and the third valve 295, and the first and second orifices 291 and 292 are regulated by using the pressure regulator concerned and the pressure gauge, whereby pressures of the gases supplied from these first and second orifices 291 and 292 can be constantly maintained.

As described above, in the present invention, the deposition is performed while maintaining the pressure in the processing chamber 21 in the molecular flow region (the first step), and on the other hand, the gas pressure is changed from the molecular flow region to the viscous flow region during the period while the deposition is not being performed (the second step), whereby the contamination on the substrate on which the deposited thin film is formed, and particularly, the contamination by the organic substances can be suppressed. In this case, the gas pressure in the processing chamber 21 in the first step is set to be lower than the gas pressure in the second step, whereby the gas pressure can be changed from the molecular flow region to the viscous flow region.

### INDUSTRIAL APPLICABILITY

As described above, the present invention can be applied not only to the manufacture of the semiconductor device but also to the process that requires the film forming by the deposition in the manufacture of the electronic device using the glass substrate, such as the liquid crystal display device and the organic EL device. Further, the present invention can also be used for creating film.

1-15. (canceled)

16. A reduced pressure deposition method of performing deposition processing in a chamber capable of varying an inner pressure thereof, the reduced pressure deposition method comprising:
a first step of maintaining a pressure in the chamber in a molecular flow region; and
a second step of changing the pressure in the chamber from the molecular flow region to a viscous flow region,
wherein contamination on the deposited film is thereby reduced.

17. A reduced pressure deposition method according to claim 16, wherein the deposition is performed during the first step, and the second step is performed during a period while the deposition is not being performed.

18. A reduced pressure deposition method according to claim 17, wherein a gas pressure in the chamber differs between the first step and the second step, and the gas pressure in the second step is higher than the gas pressure in the first step.

19. A reduced pressure deposition method according to claim 16, wherein, in the first step, a gas pressure in the chamber is set to 0.1 mTorr to 1 mTorr so that the gas pressure is maintained in the molecular flow region, and in the second step, the gas pressure in the chamber is set to 1 Torr or higher so that the gas pressure is set in the viscous flow region.

20. A reduced pressure deposition method according to claim 19, wherein the gas pressure in the second step is 10 Torr or higher.

21. A reduced pressure deposition method according to claim 16, wherein the chamber is enabled to be supplied with inert gas and the chamber is enabled to be exhausted in advance, and a gas flow rate of the supplied inert gas is controlled and an exhaust velocity of the exhaustion is controlled, thereby realizing gas pressures of the molecular flow region and the viscous flow region.

22. A reduced pressure deposition method according to claim 21, wherein the inert gas is at least one of high-purity nitrogen, argon, xenon and krypton.

23. A deposition method for an organic EL film, comprising depositing the organic EL film by using the reduced pressure deposition method according to claim 16.

24. A manufacturing method for an organic EL film, comprising the step of depositing the organic EL film by using the reduced pressure deposition method according to claim 16.

25. A manufacturing method for an electronic device, comprising the step of forming a film by using the reduced pressure deposition method according to claim 16.

26. A reduced pressure deposition method, comprising:
setting a pressure of an atmosphere where a deposited film is formed to a gas pressure of a molecular flow region at a time of forming the deposited film; and
setting the pressure of the atmosphere to a gas pressure of a viscous flow region at least in a certain period during a time when the deposited film is not formed.

27. The reduced pressure deposition method according to claim 26, wherein the gas pressure of the molecular flow region at the time of forming the deposited film is approximately 1 mTorr or lower, and the gas pressure of the viscous flow region at the time when the deposited film is not being formed is approximately 1 Torr or higher.

28. A reduced pressure deposition method according to claim 26, wherein a main component of the atmosphere at the time of forming the deposited film and at the time when the deposited film is not formed is inert gas.

29. A reduced pressure deposition method according to claim 28, wherein the inert gas is at least one of high-purity nitrogen, argon, xenon, and krypton.

30. A deposition method for an organic EL film, comprising depositing the organic EL film by using the reduced pressure deposition method according to claim 26.

31. A deposition method for an organic EL film, comprising the step of depositing the organic EL film by using the reduced pressure deposition method according to claim 26.

32. A manufacturing method for an electronic device, comprising the step of forming a film by using the reduced pressure deposition method according to claim 26.
